(19) United States
(12) Patent Application Publication
(10) Pub. No.: US 2026/0286561 A1
(43) Pub. Date: Sep. 24, 2026

(54) AUTOMATED SWITCHING BETWEEN WAFER PATTERN SPECIFIC DIFFUSERS

(71) Applicant: Applied Materials, Inc., Santa Clara, CA (US)

(72) Inventors: Paul R. MCHUGH, Kalispell, MT (US); Nolan L. ZIMMERMAN, Kalispell, MT (US); Gregory J. WILSON, Kalispell, MT (US)

(21) Appl. No.: 19/574,873

(22) Filed: Mar. 23, 2026

Related U.S. Application Data
(60) Provisional application No. 63/776,764, filed on Mar. 24, 2025.
(60) Provisional application No. 63/778,597, filed on Mar. 27, 2025.

(51) Int. Cl. C25D 5/02; H10P 14/47

(52) U.S. Cl. CPC C25D 5/022; H10P 14/47

(57) ABSTRACT

Embodiments of the present disclosure generally relate to a semiconductor processing chamber including a vessel, a substrate support having a substrate support surface positionable in the vessel; an anode and a diffuser, the diffuser having a first sub-plate and a second sub-plate, the first sub-plate positionable on the second sub-plate in at least a first position and a second position, a portion of a first substrate specific pattern of openings disposed in the first sub-plate at a plurality of first locations of the first plate and a portion of a second substrate specific pattern of openings disposed in the first sub-plate at a plurality of second locations of the first sub-plate different than the first locations, a portion of a first substrate specific pattern of openings disposed in the second sub-plate at a plurality of first locations of the second sub-plate and a portion of a second substrate specific pattern disposed in the second sub-plate at a plurality of second locations of the second sub-plate different than the first locations, and in the first position of the first sub-plate over the second sub-plate, the first and second portions of the first substrate specific pattern are positioned to express the first substrate specific pattern, and in the second position of the first sub-plate over the second sub-plate, the first and second portions of the second substrate specific pattern are positioned to express the second substrate specific pattern.

### BACKGROUND

### CROSS-REFERENCE TO RELATED APPLICATIONS

This application claims benefit of U.S. provisional patent application Ser. No. 63/776,764, filed Mar. 24, 2025 and U.S. provisional patent application Ser. No. 63/778,597, filed Mar. 27, 2025. Both applications are herein incorporated by reference.

### FIELD

The present technology relates to methods, components, and apparatuses for semiconductor manufacturing. More specifically, the present technology relates to substrate electroplating equipment and components thereof, and other semiconductor processing equipment.

### DESCRIPTION OF THE RELATED ART

Microelectronic devices, such as semiconductor devices, are fabricated on and/or in substrates such as semiconductor wafers or other types of work pieces. One process useful for the fabrication of such devices is electroplating, where a metal is deposited on portions of a seed layer exposed through openings in an overlying resist lor mask layer. A typical substrate plating process involves first depositing a metal seed layer onto the surface of the substrate via vapor deposition. A photoresist may be deposited over the seed layer and patterned to create islands of photoresist and interspersed portions of the seed layer exposed through openings in the photoresist. The substrate is then moved into the vessel of an electroplating processor where electric current is conducted between an anode, through an electrolyte to the surface of the seed layer exposed in the openings in the photoresist and in contact with the electrolyte, to deposit a blanket layer on the seed layer where no photoresist is present, or deposit a patterned layer of a metal or other conductive material onto the exposed portions of the seed layer in the openings in the photoresist. Examples of conductive materials include permalloy, gold, silver, copper, cobalt, tin, nickel, and alloys of these metals. Subsequent processing steps form components, contacts and/or conductive lines on the substrate. Many aspects of an electroplating process may impact process uniformity, such as irregularities in the electric field due to exposed metal seed pattern variations, mass-transfer rates in the electrolyte, as well as other process and component parameters. Additionally, the surface area of exposed portions of the seed layer to be plated per square millimeter or square centimeter of the substrate or work piece on the to be plated surface side thereof can vary significantly across the substrate or work piece. This variation in plateable seed layer density across the substrate can also lead to variations in the deposition thickness across the substrate or work piece. Even minor discrepancies in the surface features and plating properties across a substrate may impact finishing processes occurring after the plating process is completed.

Conventional electroplating chambers and methods lead to high Total Thickness Variation (hereafter TTV) when processing large die patterns that include significant area density variations and also have a pattern perimeter that does not extend to the edge of the substrate. Controlling the TTV using conventional means often requires low plating rates, which results in low throughput. Designs that yield lower TTV enable higher plating rates and therefore higher substrate throughput, which is a desirable factor in producing microelectronic devices. Additionally, where a first substrate has a first variation in plateable seed layer density thereacross, and a second substrate has a second, different, variation in plateable seed layer density thereacross, it is difficult to impossible to obtain a desirable TTV on both substrates when plated in the same chamber with the same chamber hardware. This limits the utility of the plating hardware as dedicated to a single substrate type, or requires shutting down the system and replacing components thereof designed to obtain a desirable TTV on the second substrate.

Thus, there is a need for improved systems and methods that can be used to produce high quality devices and structures with acceptable TTV with greater flexibility of the plating hardware.

### SUMMARY

Embodiments of the present disclosure generally relate to a semiconductor processing chamber, and more particularly, an electroplating system and methods of processing substrates. In one aspect, a plating system is provided, and it includes a vessel, a substrate support having a substrate support surface positionable in the vessel, an anode, a diffuser, the diffuser comprising a first sub-plate and a second sub-plate, the first sub-plate positionable in at least a first position and a second position relative to the second sub-plate in at least a first position and a second position, the diffuser including a first substrate specific pattern of openings and a second substrate specific pattern of openings, a first portion of a first substrate specific pattern of opening disposed in the first sub-plate at a plurality of first locations of the first plate and a first portion of a second substrate specific pattern of openings disposed in the first sub-plate at a plurality of second locations of the first sub-plate different than the first locations of the first sub-plate, a second portion of a first substrate specific pattern of openings disposed in the second sub-plate at a plurality of first locations of the first plate and a second portion of a second substrate specific pattern of openings disposed in the second sub-plate at a plurality of second locations of the second sub-plate different than the first locations of the second sub-plate, and in the first position of the first sub-plate over the second sub-plate, the first and second portions of the first substrate specific pattern of openings are positioned to express the first substrate specific pattern of openings extending through the diffuser, and in the second position of the first sub-plate over the second sub-plate, the first and second portions of the second substrate specific pattern of openings are positioned to express the second substrate specific pattern of openings extending through the diffuser.

In another aspect hereof, a diffuser for a plating system includes a first sub-plate and a second sub-plate, the first sub-plate positionable on the second sub-plate in at least a first position and a second position, a portion of a first substrate specific pattern of openings extending through the first sub-plate and disposed in the first sub-plate at a plurality of first locations of the first plate and a portion of a second substrate specific pattern of openings extending through the second sub-plate and disposed in the first sub-plate at a plurality of second locations of the first sub-plate different than the first locations of the first sub-plate, a portion of a first substrate specific pattern of openings extending through the second sub=plate disposed in the second sub-plate at a plurality of first locations of the first plate and a portion of a second substrate specific pattern of openings extending through the second sub-plate and disposed in the second sub-plate at a plurality of second locations of the second sub-plate different than the first locations of the second sub-plate, and in the first position of the first sub-plate over the second sub-plate, the first and second portions of the first substrate specific pattern of openings are positioned to express the first substrate specific pattern of openings through the diffuser, and in the second position of the first sub-plate over the second sub-plate, the first and second portions of the second substrate specific pattern of openings through are positioned to express the second substrate specific pattern of openings through the diffuser.

[symbol]

another aspect hereof, a method of plating at least two different plateable patterns on two different substrates in the same plating vessel includes providing a vessel, providing a substrate support having a substrate support surface positionable in the vessel, providing an anode in the vessel, positioning a diffuser between the anode and the substrate support, the diffuser comprising a first sub-plate and a second sub-plate, the first sub-plate positionable in at least a first position and a second position relative to the second sub-plate in at least a first position and a second position, the diffuser including a first substrate specific pattern of openings expressible when the first sub-plate and second sub-plate are in the first position, and a second substrate specific pattern of openings when the first sub-plate and the second sub-plate are in the second position.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1A is a plan view of a substrate that includes multiple large die patterns that include area density variations, in other words, areas of different density of plateable surface area.

FIG. 1B is a close-up plan view of a one of the multiple large die patterns that includes a plurality of area density variations.

FIG. 2A is isometric view of an electroplating chamber, according to embodiments of the disclosure.

FIG. 2B is isometric view of a portion of the electroplating chamber illustrated in FIG. 2A with the substrate support removed, according to embodiments of the disclosure.

FIG. 3 is a partial schematic side cross-sectional view of a first configuration of the electroplating chamber shown in FIGS. 2A-2B, according to one or more embodiments.

FIG. 4 is a schematic partial sectional view of a plating chamber according to one or more embodiments.

FIG. 5A is a plan view of second sub-plate of a diffuser with a representative die pattern overlaid on a portion of the sub-plates, and plurality of slots therebetween, according to one or more embodiments.

FIG. 5B is a plan view of first sub-plate of a diffuser with a representative die pattern overlaid on a portion of the first sub-plate, and a plurality of slots therebetween, according to one or more embodiments.

FIG. 5C is a plan view of repeating die specific opening layout used in the second sub-plate according to one or more embodiments.

FIG. 6A is a partial schematic side cross-sectional view of a first configuration of a diffuser disposed within the upper portion of the electroplating chamber according to one or more embodiments.

FIG. 6B is a partial schematic side cross-sectional view of a second configuration of the diffuser of FIG. 6B disposed within the upper portion of the electroplating chamber according to one or more embodiments.

FIG. 7 is a perspective view of the diffuser, a paddle and a substrate as located in a plating vessel.

FIG. 8 is a partial plan view of the plating vessel of FIG. 4.

FIG. 9 is a perspective view of an additional configuration of the diffuser.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to a semiconductor processing chamber, and more particularly, an electroplating chamber assembly that includes a chamber geometry configured to improve an electroplating deposition uniformity within a processing chamber, and related methods. Embodiments of the present disclosure generally relate to a semiconductor processing chamber, and more particularly, an electroplating system and methods of processing substrates that include multiple large die patterns.

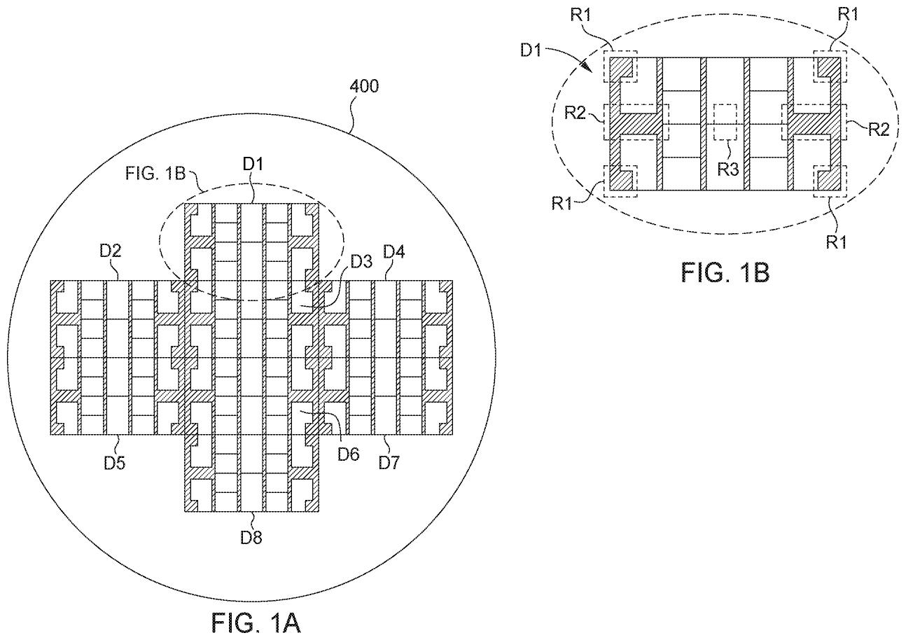

FIG. 1A is a plan view of a substrate that includes multiple large die patterns that include area plateable surface density variations within each die pattern. As shown in FIG. 1A, the substrate 400 includes eight die patterns D1-D8 that are positioned, oriented and exposed on a surface of the substrate 400. In some configurations, the dark colored regions of the die patterns include one or more exposed features that include one or more metal layers that have a varying pattern density, while the white or uncolored regions will typically include a patterned photoresist or dielectric material.

FIG. 1B is a close-up plan view of a first die pattern D1 of the plurality of die patterns that includes a plurality of area pattern density variations. In one example, the first die pattern D1 includes multiple regions that can be characterized as falling within one of three different average plateable surface area pattern densities R1-R3. In the examples provided herein, it is assumed that each of die patterns D1-D8 include one or more regions that include a first plateable surface area pattern density R1, one or more regions that include a second plateable surface area pattern density R2, and one or more regions that include a third plateable surface area pattern density R3, wherein the pattern density of the first plateable surface area pattern density R1 is less than the second plateable surface area pattern density R2, which is less than the third plateable surface area pattern density R3. Due to the variation in plateable surface area pattern density, the plating rate and thus TTV within the different area pattern density regions during a plating process will have significant variations across the die patterns D1-D8.

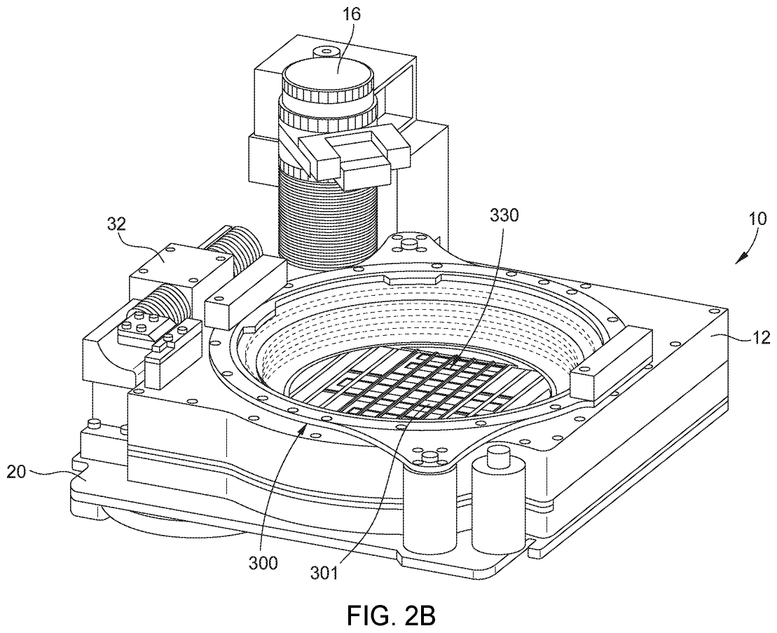

The technology disclosed herein overcomes the challenges experienced in the industry when trying to plate metals within die patterns similar to the first die pattern D1 by incorporating components that selectively shield various regions of a substrate and die patterns from the electric field produced during electroplating operations. For example, embodiments of the present technology may utilize a shielding assembly 316 that includes a paddle 330, or a paddle 330 and a diffuser 320 (FIG. 3) that each include shield areas that correspond with and shield sparsely patterned regions (low pattern density) of a die pattern from the electric field and include open areas that enable the electric field (and fresh electrolyte) to pass through to the densely patterned regions (high or relatively pattern density) of the substrate 400 that are to be plated during an electroplating process. Here, pattern density is the area of metal exposed in the openings in the photoresist per unit area of photoresist. The use of such a shielding assembly 316 may enable plating rates within patterned regions of high pattern density and patterned regions of low or sparce pattern density to be more uniform with one another. Some embodiments may utilize a paddle 330, a diffuser 320, or a paddle 330 and a diffuser 320, that include apertures therethrough aligned with densely patterned regions that enable the electric field to pass through to the densely patterned regions of the substrate 400, while a solid face or smaller aperture within the paddle 330, diffuser 320, or paddle 330 and diffuser 320 is used to shield sparsely patterned regions from the electric field. Some embodiments may improve the Total Thickness Variation (TTV) and co-planarity of the deposited layer. Accordingly, the present technology may produce improved TTV and co-planarity of substrates during electroplating operations.

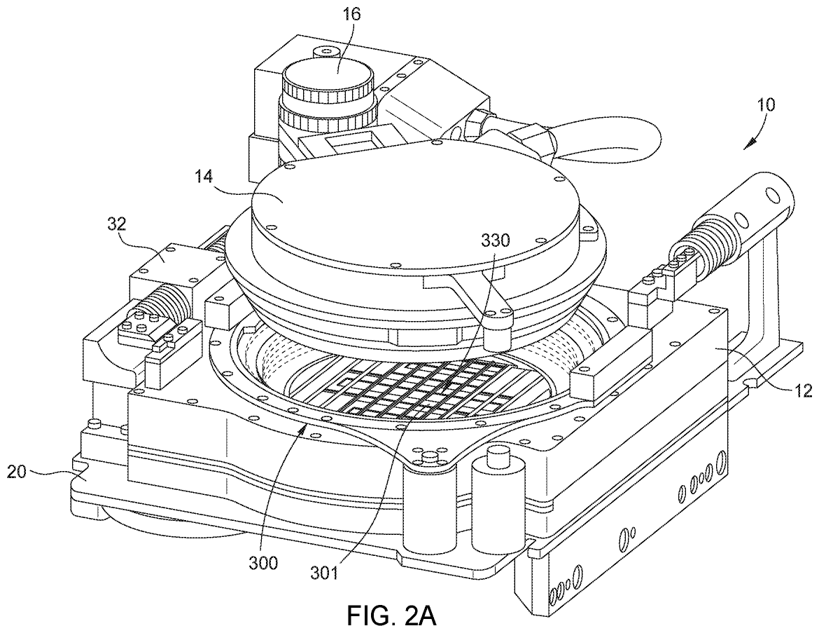

FIGS. 2A-2B illustrate an exemplary system 10 for electroplating a substrate 400 (FIG. 3) according to embodiments of the present technology. FIG. 3 is a partial schematic side cross-sectional view of a first configuration of the electroplating chamber 300 shown in FIGS. 2A-2B, according to one or more embodiments. System 10 may include a head 14 supported on a head lifter 16 and a vessel 301 in which electrolyte is circulated, and an anode A1-A3, the diffuser 320 and optional paddle 330 are housed. A single system 10 may be used as a standalone unit. Alternatively, multiple systems 10 may be provided in arrays within an enclosure, with substrates or workpieces loaded and unloaded into and out of the processors by one or more robots. Head lifter 16 may lift and/or invert the head 14 to load a substrate 400 thereon and unload a substrate 400 therefrom. Head lifter 16 may also lower the head 14 into engagement with one or more components of the vessel 301 for processing of the substrate 400 by locating the to be plated surface of the substrate in an electrolyte solution in vessel 301. A membrane 40 (FIG. 3) may be included to divide the vessel 301 into a lower chamber 309 containing one or more anodes A1-A3, and a first liquid electrolyte 307, below the membrane 40, and an upper chamber 310 containing a second liquid electrolyte 314. Alternatively the membrane 40 may be omitted with the vessel 301 having a single chamber holding a single electrolyte 314.

A contact ring (not shown) is disposed on the head 14, which is provided to hold the substrate 400 and may have a plurality of contact fingers for making electrical contact with a conductive layer, such as a metal seed layer, formed on the surface of the substrate 400 that includes the die pattern regions D1-D8. In FIG. 3, the substrate 400 is positioned in a face-down orientation so that the die pattern regions D1-D8 are positioned to contact an electrolyte 314 that flows from the upper chamber 310, through the shielding assembly 316, into a plating region 311, and then flows to the lower facing surface of the substrate 400. The head 14 may include a rotor (not shown) for rotating the substrate 400 and the contact ring during processing. The head 14 may be movable to position the substrate holder into a processing position in the vessel 301, where the metal layers within the die pattern regions are in contact with electrolyte 314 in the vessel 301. A rinse assembly 12 having tiered drain rings may be provided above and/or about the vessel 301.

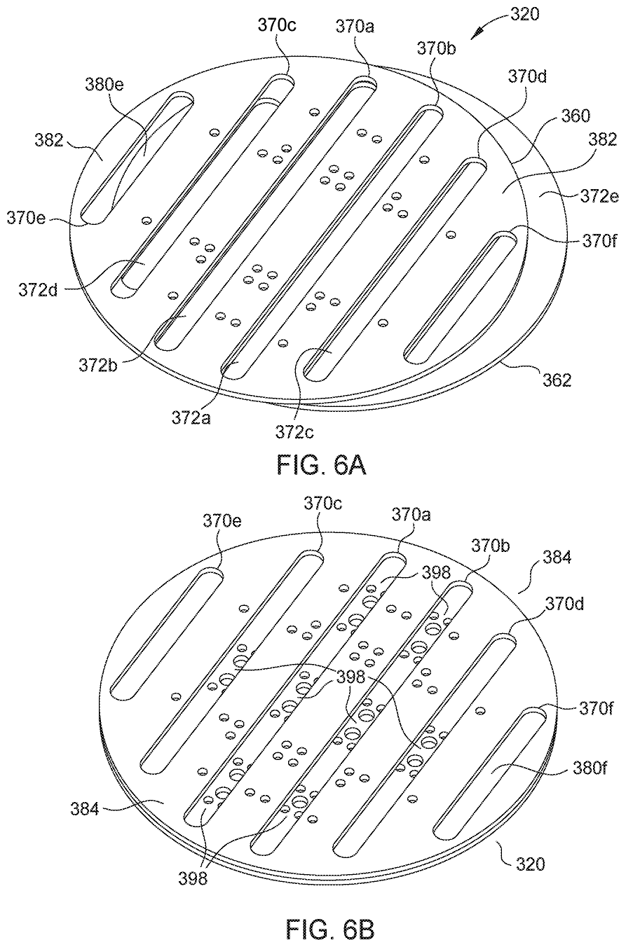

A paddle 330 is provided at a fixed vertical position within the vessel 301 adjacent to the substrate 400 and between the substrate 400 and the membrane 40 or between the substrate 400 and the anodes A1-A3 where no membrane 40 is used. In some embodiments, the paddle 330 may be a generally circular plate 334 of dielectric material having a plurality of parallel ribs or blades 335 spaced apart by slots and/or other openings (FIG. 7). A paddle actuator 350 may move the paddle 330 horizontally in a flat plane, parallel to the substrate 400, within the vessel 301 to agitate the electrolyte 314 over the plating surface of the substrate 400. The paddle 330 through the paddle actuator 350, and the paddle actuator 350, may be supported on a base plate 20 (FIG. 2B) attached to the vessel 301. The substrate 400 may be rotating or stationary during an electroplating operation. However, in some embodiments provided herein the substrate 400 is stationary for a first period of time in a first position and then rotated an angle relative to a vertical axis to a second position for a second period of time. In one example, the angle is 180 degrees. The slots and/or other openings on the paddle 330 may allow ionic current to pass through the paddle 330.

In some embodiments, the paddle 330 itself is used as an electric field shield. In typical operation, the paddle 330 may move with an oscillation (which may be between or about 6-10 Hz in some embodiments), and with a stroke that is about a half (½) to one (1) times the paddle rib pitch P1 (FIG. 3). A secondary low frequency oscillation may be used to shift the rib reversal points to avoid imprinting either an electric field or mass transfer signature on the substrate 400 (i.e., stripes on a stationary substrate 400, and rings on a rotating substrate 400). This secondary oscillation is referred to as the stagger motion. The stagger motion envelope may be roughly equal to the rib pitch P1. During processing, the paddle actuator 350 moves the paddle 330 to agitate the catholyte disposed within the plating region 311 the contained in the vessel 301. For example, the paddle 330 may move back and forth within a paddle travel dimension, with an oscillating motion. For some applications the paddle 330 may use other movements, such as start/stop, stagger, etc.

In some embodiments, additional components may be integrated into an electroplating system to improve the co-planarity of the plated substrate 400. In one example, as shown in FIG. 3, some electroplating systems 10 include a shielding assembly 316 that includes a paddle 330 and a diffuser assembly 320 that are used in combination to selectively shield portions of the substrate 400 from the electric field produced by the anodes during the plating operation to reduce electrodeposition variations within selected regions of the substrate 400, such as regions with smaller average area pattern densities (e.g., average area densities R1), while enabling the electrodeposition within higher plateable surface area density regions, such as the average area densities R3. This may help improve the co-planarity across the substrate 400. Additionally, the shielding assembly 316 can be configured without the paddle 330

In some embodiments, the shielding assembly 316 includes a diffuser assembly 320 that is mounted on and sealed to a wall of the vessel 301. The diffuser assembly 320 includes a plurality of apertures 321 through which the electrolyte 314 flowing from the upper chamber 310 (i.e., electrolyte 314 flow 315) passes and then flows through the apertures 331 in the paddle 330 and into the plating region 311 and to the surface of the substrate 400.

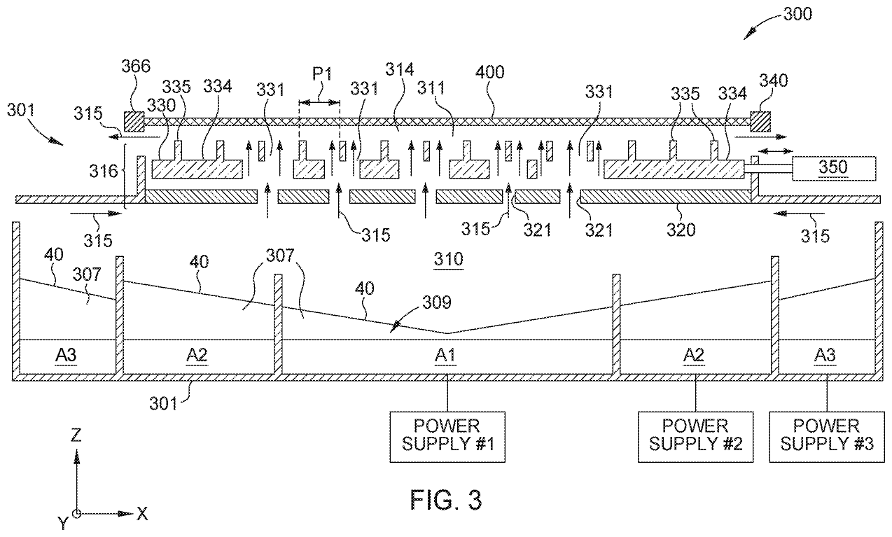

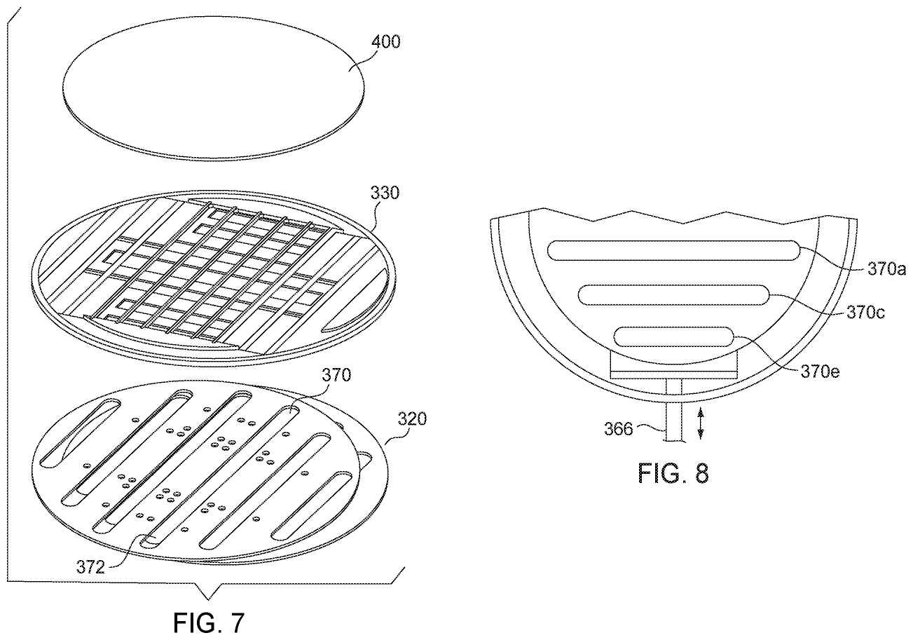

FIG. 4 is a schematic partial sectional view of the plating vessel 301, showing the position of the diffuser assembly 320 therein. Here, the diffuser assembly 320 includes two sub-plates, first and second sub-plates 360, 362, moveable with respect to each other to selectively expose, or cover, openings in the first and second sub-plates 360, 362. As shown in FIG. 4, the second sub-plate 362 is supported on a secondary ledge 364 of the wall of the vessel 301, and the first sub-plate 360 is supported thereover by resting on the second sub-plate 362, or in a separate slot in the interior side wall of the vessel 301. A sub-plate actuator 366 is connected to the side of the first sub-plate 360 at two opposed locations (FIGS. 4 and 8), and is drivable linearly and bi directionally in the directions A relative to the second sub plate 362 by a linear drive unit 368 such as a pneumatic or mechanical linear actuator.

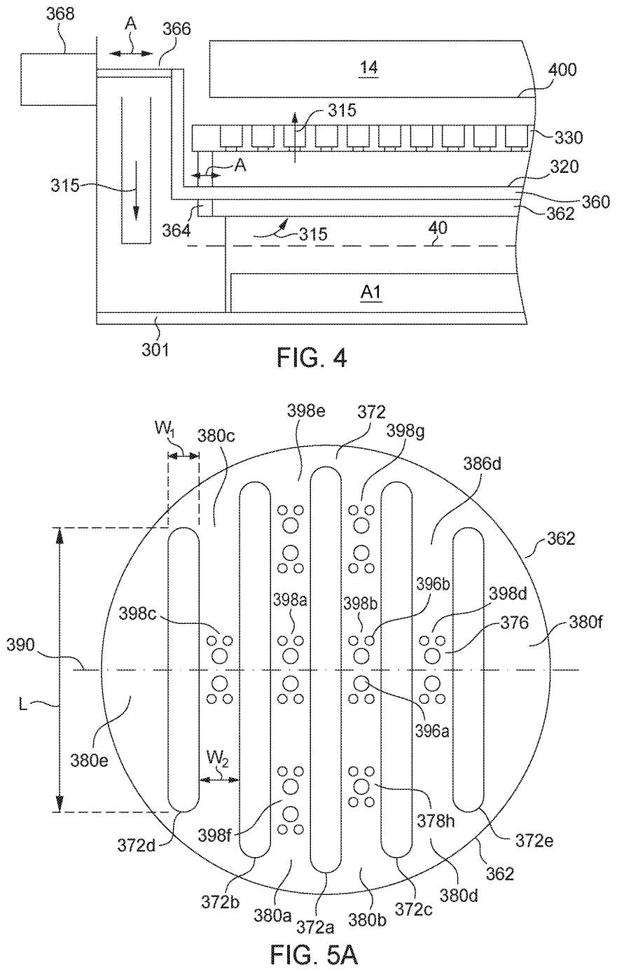

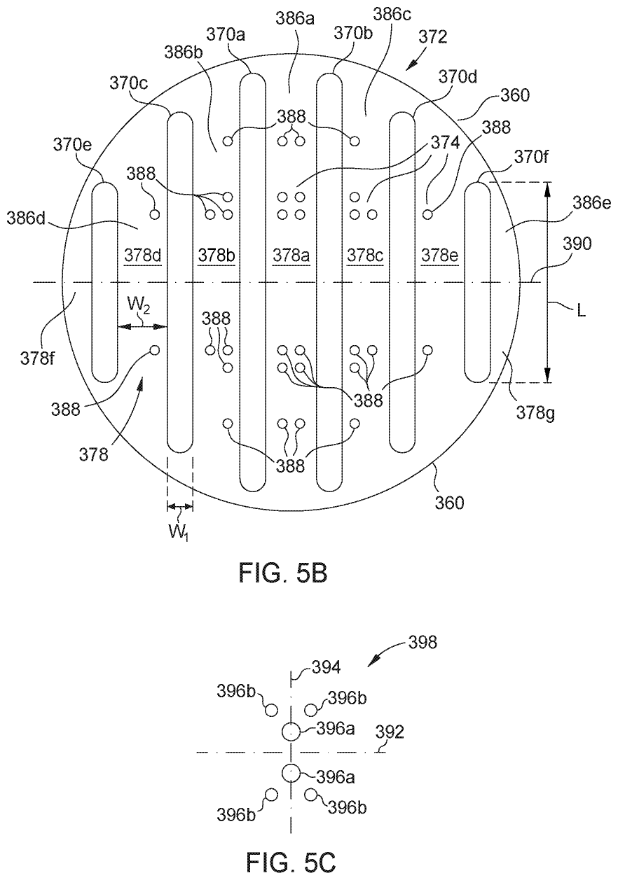

FIGS. 5A and 5B are plan views of the first and second sub-plates 360, 362 of the diffuser assembly 320, wherein the second sub-plate 362 includes second slot openings 372 (372a-e) and second pattern specific openings 376, and first sub-plate 360 includes first slot openings 370 (370a-f) and first pattern specific openings 374, which together selectively provide or express the apertures 321 in the diffuser assembly 320 through with the electrolyte can flow based on the relative positions of the first and second sub-plates 360, 362. The first slot openings 370 extend through the first sub-plate 360 and the second slot openings 372 extend through the second sub-plate 362 as longitudinal slots, parallel to one another, having a length L and a width W, and when the slot openings of the first and second sub-plates 360, 362 are aligned provide a first expressible pattern 382 extending through the diffuser assembly 320 as shown in FIG. 6A, to allow electrolyte to flow therethrough, to allow electrolyte to flow therethrough. First and second pattern specific openings 374, 376 together provide a second expressible pattern 384 when the first sub-plate 360 and the second sub-plate 362 are aligned as shown in FIG. 6B. Here, for example, the first expressible pattern 382 is useful for blanket deposition on a substrate 400 or on substrates having large open areas to be plated thereon, while the second expressible pattern 384 shown in FIG. 6B is configured to plate a pattern having large, medium and small area features in each die with acceptable TTV. First and second sub-plates 360, 362 are configured of any chemically compatible, to the electrolyte 314, plastic (PPO, PEEK, NPP, PVDF, etc.), a ceramic, or other rigid chemically compatible material such as Titanium. As will be further described herein, in the configuration of the first and second sub-plates 360, 362 of FIGS. 5a to 6B, the composition thereof is preferably a dielectric.

First sub-plate 360 is here a thin plate having sufficient rigidity to insignificantly deform under the pressure of the electrolyte 314 flowable therethrough or the side force imposed thereon to move it linearly with respect to the second sub-plate 362. In the embodiment shown, the first sub-plate 360 includes a plurality of first slot openings 370a to 370f extending parallel to one another and separated by intervening first lands 378. Each slot opening 370-370f has the same width W1. Here the slot openings 370 are configured such that three sets of two slot openings 370, i.e., pairs of slot openings 3703, each slot opening 370 of a pair of slot openings 370 having the same length in the direction normal to the width W1 direction. Thus the pair of slot openings 370a, 370b, form a pair of slot openings 370, the pair of slot openings 370c, 370d form a pair of slot openings 370, and the pair of slot openings 370e, 370f form a pair of slot openings 370, each slot opening 370 in each pair of slot openings 370 have the same length, where slot openings 370a, 370b have the longest length L, slot openings 370e, 370f have the shortest length L, and slot openings 370c, 370d have a length L between that of slot openings 370a, 370b and slot openings 370e, 370f.

First lands 378a-e here all have the same width W2 which is greater than W1, such that the first slot openings 370 are equally spaced from one another in the direction normal to the length direction thereof and are generally parallel to one another in the length direction L of the first slot openings 370. Land 378a extends between slot opening 370a and slot opening 370b and is generally centered in first sub-plate 360, land 378b extends between slot opening 370a and slot opening 370c, land 378c extends between slot opening 370b and slot opening 370d, land 378d extends between slot opening 370c and slot opening 370e, and land 378e extends between slot opening 370d and slot opening 370f. A smaller crescent shaped land 378f extends between the edge of the first sub-plate 360 and the adjacent long side of slot opening 370e, and a smaller crescent shaped land 378g extends between the edge of the first sub-plate 360 and the adjacent long side of slot opening 370f.

Second sub-plate 362 has a similar slot opening pattern as that of first sub-plate 360, except that it has one fewer slot opening and one fewer land as compared to the first sub-plate 360. Second sub-plate 362 includes second slot opening s 372a-370e spaced from one another and extending parallel to one another in the direction L, and each having the same slot width W1 as that of slot openings 370a-f in first sub-plate 360, and each second slot opening 372 is separated from an adjacent second opening slot 372 by second lands 380 having the same width W2 as that of the first lands 378a-e. Here, second slot opening 372a is disposed between second slot opening 370b and second slot opening 372c, and is generally centered in the second sub-plate 362. Second slot opening 372b is located between second slot opening 372d and second slot opening 372a, and second slot opening 372b is located between second slot opening 372a and second slot opening 372e. In the second sub-plate 362, the second slot openings 372 have three different lengths L, where second slot opening 372a is longer than any other second slot opening 372b-372e, second slot openings 372d and 372e have the same length L, which is shorter than second slot opening s 372a-c, and second slot openings 372b, 372c have the same length L, which is less than the length of second slot opening 372a and shorter than the length of second slot openings 372d, 372e. Second lands 380 have the same width W2 as that of the first lands of first sub-plate 360, which is greater than the width W1 of the second slot openings 372. Second land 380a is located between second slot opening 372a and second slot opening 372b, second land 380b is located between second slot opening 372a and second slot opening 372c, second land 380c is located between second slot opening 372b and second slot opening 372d, and second land 380d is located between second slot opening 372c and second slot opening 372e. Additionally, a larger crescent shaped land 380e extends between second slot opening 372d and the adjacent side wall of the second sub-plate 362, and a larger crescent shaped land 380f extends between second slot opening 372e and the adjacent side wall of the second sub-plate 362.

The first lands 378a-e of the first sub-plate 360 include a first portion of the second expressible pattern 376, here the first pattern specific openings 374, and they are provided as first opening groups 386 having generally circular in section first sub-plate openings 388 extending through the first sub-plate 360 to allow plating fluid or electrolyte to flow therethrough. Here, the first sub-plate openings 388 of each first opening group 386 are disposed in symmetry about an imaginary line 390 extending through the center in the length direction L of each of the first slots 370a to 370e. A first opening group 386a includes twelve first sub-plate openings 388, with a grouping of four first sub-plate openings 388, with the openings disposed at the four corners of an imaginary rectangle, disposed about the center of first land 378a on either side of the imaginary line 390 and equally spaced therefrom, and two first sub-plate openings 388 spaced from one another in a direction parallel to the imaginary line 390, and disposed about the center of first land 378a on either side of the imaginary line 390 and equally spaced therefrom and outwardly of the location of the sets of four first sub-plate openings 388.

A second opening group 386b and third opening group 386c have the same patterns, but in symmetry to each other about the center of the first land 378a in the length L direction thereof. Second opening group 386b and third opening group 386c each include eight first sub-plate openings 388, four to each side of imaginary line 390. Three first sub-plate openings 388 are disposed first sub-plate openings 388, and spaced from one another about three corners of an imaginary rectangle, and a single first sub-plate opening 388 is disposed outwardly of the set of three first sub-plate openings 388, at generally the same distance that the two first sub-plate openings 388 are spaced from the imaginary line 390 on the first land 378a. In lands 378d and 378e, fourth and fifth opening groups 38cd, e include only a single first sub-plate opening 388 disposed on either side of the imaginary line 390 by the same distance that the closest of the four first sub-plate openings 388 on the first land 378a are disposed.

Openings also extend through the lands 386a-d of the second sub-plate 362 to allow fluid or electrolyte flow therethrough, and are provided as a second sub-plate opening groups 398 ss shown in FIG. 5C, having two larger second sub-plate openings 396a disposed to either side of a first axis of symmetry 392, centered on a second axis of symmetry 394 extending normal to the first axis of symmetry 392and equally spaced from the first axis of symmetry 392, and four smaller second sub-plate openings 396b. approximately equal in cross section to first sub-plate openings 388, disposed in a generally rectangular pattern about the larger second sub-plate openings 396a, with two of the smaller second sub-plate openings 396b spaced from one another on either side of the first axis of symmetry 392 at an equal distance from the first axis of symmetry 392, and also disposed on a first side of the second axis of symmetry 394 and spaced therefrom by a distance greater than the radius of the larger second sub-plate openings 396a, and the other two of the smaller second sub-plate openings 396b spaced from one another on either side of the first axis of symmetry 392 at an equal distance from the first axis of symmetry, and also disposed on a second side of the second axis of symmetry 394 and spaced therefrom by a distance greater than the radius of the larger second sub-plate openings 396a. The two smaller second sub-plate openings 396b on the first side of the second axis of symmetry 394 are spaced from the second axis of symmetry 394 by the same distance as the two smaller sub-plate openings 396b are disposed from the second axis of symmetry.

As shown in FIG. 5A, second sub-plate opening groups 398 are provided to extend through second sub-plate 362. Second sub-plate opening group 398a is centered in second land 380a between slot openings 372a and 372b, and the first axis of symmetry 392 thereof is centered on imaginary line 390 which also extends through the center, in the length L direction, of each of the second slot openings 372a-372e. Second sub-plate opening group 398b is centered in second land 380b between second slot openings 372a and 372c, and the first axis of symmetry 392 thereof is centered on imaginary line 390. Second sub-plate opening group 398c is centered in second land 378c between second slot openings 372a and 372c, and the first axis of symmetry 392 thereof is centered on imaginary line 390. Second sub-plate opening group 398c is centered in second land 380c is centered between second slot openings 372b and 372d, and the first axis of symmetry 392 thereof is centered on imaginary line 390. Second sub-plate opening group 398d is centered in land 380d between second slot openings 372c and 372f, and the first axis of symmetry 392 thereof is centered on imaginary line 390.

Two additional second sub-plate opening groups 398 are disposed to either side of the imaginary line 390, and spaced equally therefrom by generally the same distance and thus spaced from the second sub-plate opening groups 398 centered on the imaginary line. Second sub-plate opening group 398e is centered in second land 380a on a first side of the imaginary line 390, and second sub-plate opening group 398f is centered in second land 380a on a second side of the imaginary line 390. Second sub-plate opening group 398g is centered in second land 380b on a first side of the imaginary line 390, and second sub-plate opening group 398h is centered in second land 380b on a second side of the imaginary line 390.

The widths W1 and W2 of the slot openings and lands are selected to enable expressing only one or the other of the first and second expressible patterns 382, 384. Thus, when the first expressible pattern 382 is expressed by locating the first sub-plate 360 in a first position relative to the second sub-plate 362 as shown in FIG. 6A where first and second slot openings 370, 372 align to allow electrolyte to flow therethrough and thus through the diffuser 320, the first lands 378 of the first sub-plate 360 overlie the second lands of the second sub-plate 362 thereby blocking flow of fluid or electrolyte through the first and second sub-plate opening groups 386, 398. Because the first plate openings 388 in the first sub-plate 360 are all located at a different distance from imaginary line 390 than are the second sub-plate openings 396a, 396b in the second sub-plate opening groups 398, no direct flow path for fluid electrolyte 314 extends from through the first sub-plate openings 388 through the second sub-plate openings 396a, 396b. A seal (not shown) can be provided about each of the first sub-plate openings 388 on the side facing the second sub-plate 392 to seal against the second sub-plate 362, and a seal (not shown) can be provided around each of the second sub-plate patterns 398 on the side thereof facing the first sub-plate 360. Here, the first and second sub-plates 360, 362 can be biased apart by a compressible gasket extending along their facing perimeters, which gasket, when fluid is flowing through the slots becomes compressed to cause the seals on the first and second sub-plates 360, 362 surrounding the openings to contact the facing surface of the other sub-plate plate to prevent fluid slow therethrough.

To express the second expressible pattern 384, first plate 360 is moved laterally over second sub-plate 362, to position each of the first slot openings 370a-370d over one of second lands 398a-398d, and first slot opening 370e fully overlies second crescent shaped land 380e, and first slot opening 370f fully overlies second crescent shaped land 380f as shown in FIG. 6B, preventing electrolyte flow through the diffuser 320 via the first and second slot openings 370, 372. Here, a seal can be provided surrounding the first slot openings 370 on the side thereof facing the second sub-plate 362, and around the second slot openings 372 on the side thereof facing the first sub-plate, such that fluid flowing though the openings in the second expressible pattern 384 causes the first and second sub-plates 360, 362 to be biased against each other to effectuate a seal to prevent fluid flow through the second slot openings 372 and then through the first slot openings 370. Here, the openings in the second sub-plate opening groups 398 are located to flow through first slots 370a, 370b, 370c and 370d, and flow through second slots 372a to 372e only through the first openings 378 in the second sub-plate 362.

Referring to FIG. 7, the relationship between the diffuser assembly 320, the paddle 330 and a substrate 400 (mounted to the head 14 (FIG. 1) is shown. Paddle 330 is preferably configured of any chemically compatible, to the electrolyte, plastic (PPO, PEEK, NPP, PVDF, etc.), a ceramic, or other rigid chemically compatible material such as Titanium, and has a higher resistivity than the material of the diffuser assembly 320. The diffuser assembly 320 is disposed with the facing surface to the paddle 330 thereof generally parallel to the facing surface of the paddle 330, and the spacing therebetween ins at least as large or larger than the width W2 of the first and second lands 378, 398. As a result, when the diffuser assembly 320 is configured to express the first expressible pattern 382, the first and second lands 378, 398 become electrically invisible to the substrate 400, and deposition uniformity across the plated surface of the substrate 400 is not impacted by the presence of the first and second lands 378, 398. When a substrate 400 having a multi-pattern density, such as a die similar to the packaging die of FIG. 1, is to be plated, and for which the second expressible pattern 384c is configured in the diffuser 320, the first sub-plate 360 is shifted relative the second sub-plate 362 to the relative position thereof in FIG. 6B, and the second expressible pattern 384 is thereby expressed.

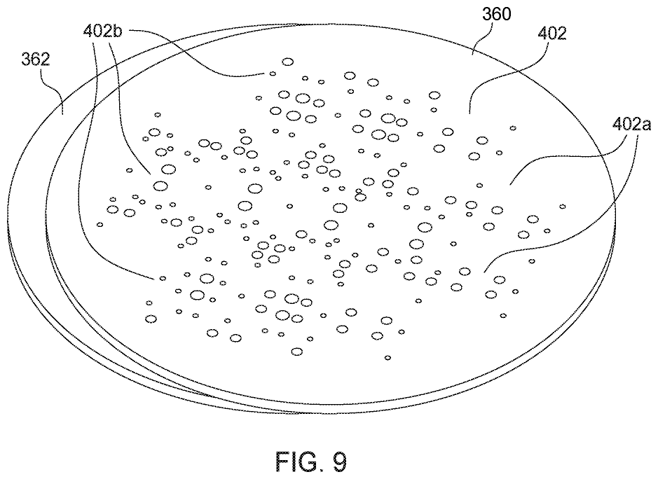

Additionally, the first and second sub-plates 360, 362 can be modified, so as not to include slot openings, and instead the slot openings are replaced with pattern specific openings extending the through the first and second sub-plates 360, 362. This modification is shown in FIG. 9, where the first sub-plate 360 includes a first portion of two different substrate pattern specific openings a, b extending therethrough, and the second sub-plate 362 includes a second portion of the two different substrate pattern specific openings extending therethrough (Not shown). Thus, each sub-plate includes alternating stripe of one half of a first substrate specific pattern and one half of a second substrate specific pattern. In a first alignment of the first sub-plate 360 over the second sub-plate, the openings of the first substrate specific pattern are aligned, but the openings of the second substrate specific pattern are not aligned, in the direction normal the surface of the first and second sub-plates 360, 362, and fluid flows through the diffuser assembly 320 through the first substrate specific pattern 402 of openings. In a second alignment of the first sub-plate 360 over the second sub-plate 362, the openings of the second substrate specific pattern are aligned, but the openings of the first substrate specific pattern 402 are not aligned, in the direction normal the surface of the first and second sub-plates 360,362, and fluid flows through the diffuser assembly 320 through the second substrate specific pattern of openings.

The first and second sub-plates 360, 362 of FIGS. 5A and 5B can also be modified to include portions of two different substrate specific patterns thereon. For example first portions of the first die specific pattern are located to a first side of each slot opening 370, and a first portion of a second die specific pattern located on the opposed side of the slot opening 370 in the first sub-plate 360, with a first portion of each of the first end second die specific pattern thus located between each two adjacent slot openings 370. Likewise, a second portion of the first die specific pattern can be located to a first side of each slot opening 372, and second portion of a second die specific pattern located on the opposed side of the slot opening 372 in the second sub-plate 362, with a second portion of each of the first end second die specific pattern located between each two adjacent slot openings. Here, the first sub-plate 360 is positionable at three locations with respect to the second sub-plate 362. In a first relative position, slot openings 370, 372 are aligned and electrolyte flows only through them. In a second relative position, the portions of the first die specific pattern in the first and second sub-plates 360, 362 are aligned and electrolyte only flows through them. In a third position, the portions of the second die specific pattern in the first and second sub-plates 360, 362 are aligned, and electrolyte only flows through them.

The terms wafer, substrate or work piece, as used herein, can include any type of semiconductor substrate, packaging substrate, substrate carrier, interposer substrate, bridge substrate, printed circuit board (PCB), or other type of substrate that includes die patterns disposed on a surface of a substrate. In some embodiments, the die pattern containing substrate can include an advanced packaging substrate that may include a material such as glass, silicon, ceramic, or organic or polymeric (e.g., FR4, BT, polyimide (PI), polyester, etc.) containing materials. The advanced packaging substrates can include one or more redistribution layers (RDL). The substrates can also be square, rectangular, or circular in shape. In one example, a square 310 mm×310 mm or 600 mm×600 mm panel is used. In some cases, where a non-circular substrate is used, the non-circular substrate can be mounted to a circular shaped carrier substrate during processing. Additionally, where a substrate having a rectangular edge or perimeter or other perimeter architecture, the paddle 330 and the first and second subplates 360, 362 can likewise be rectangular, and preferably larger in perimeter size than at least one of the perimeter of the patterned area on the substrate to be plated, or the perimeter of the substrate on which plating is to be performed.

While the foregoing is directed to embodiments of the present disclosure, other and further embodiments of the disclosure may be devised without departing from the basic scope thereof, and the scope thereof is determined by the claims that follow.

What is claimed is:

1. A plating system, comprising;
a vessel;
a substrate support having a substrate support surface positionable in the vessel;
an anode;
a diffuser, the diffuser comprising a first sub-plate and a second sub-plate, the first sub-plate positionable in at least a first position and a second position relative to the second sub-plate in at least a first position and a second position, the diffuser including a first substrate specific pattern of openings and a second substrate specific pattern of openings;
a first portion of a first substrate specific pattern of opening disposed in the first sub-plate at a plurality of first locations of the first plate and a first portion of a second substrate specific pattern of openings disposed in the first sub-plate at a plurality of second locations of the first sub-plate different than the first locations of the first sub-plate;
a second portion of a first substrate specific pattern of openings disposed in the second sub-plate at a plurality of first locations of the first plate and a second portion of a second substrate specific pattern of openings disposed in the second sub-plate at a plurality of second locations of the second sub-plate different than the first locations of the second sub-plate; and
in the first position of the first sub-plate over the second sub-plate, the first and second portions of the first substrate specific pattern of openings are positioned to express the first substrate specific pattern of openings extending through the diffuser, and in the second position of the first sub-plate over the second sub-plate, the first and second portions of the second substrate specific pattern of openings are positioned to express the second substrate specific pattern of openings extending through the diffuser.

2. The plating system of claim 1, wherein the first and second portions of the first substrate specific pattern of openings are a series of elongated slot openings spaced from, and parallel to, one another extending through the first sub-plate and the second sub-plate.

3. The plating system of claim 1, wherein the first and second portions of the second substrate specific pattern of openings are a plurality of openings extending through the first and second sub-plates in the regions of the first and second sub-plates between the first and second portions of the first substrate specific pattern.

4. The plating system of claim 1, wherein the second portion of the second substrate specific pattern of openings in the second sub-plate is disposed below a portion of the first portion of the first substrate specific pattern of openings when the first sub-plate is located over the second sub-plate in the second position.

5. The plating system of claim 1, wherein the first and second portions of the first substrate specific pattern of openings are a plurality of openings extending in alternating strips through the first and second sub-plates, and the first and second portions of the second substrate specific pattern of openings are a plurality of openings extending through the first and second sub-plates between the strips of openings of the first substrate specific pattern of openings.

6. The plating system of claim 5, wherein the first substrate specific pattern of openings comprises elongated slot openings extending through the first sub-plate between discrete portions of the second patterns of openings therein, and elongated slot openings extending through the second sub-plate between discrete portions of the second patterns of openings therein.

7. The plating system of claim 5, wherein in the first position of the first sub-plate over the second sub-plate, the first and second portions of the first substrate specific pattern of openings are aligned.

8. The plating system of claim 7, wherein in the second position of the first sub-plate over the second sub-plate, the first portion of the first substrate specific pattern of openings is aligned with the second portion of the second substrate specific pattern of openings, and the second portion of the first substrate specific pattern of openings is aligned with the first portion of the second substrate specific pattern of openings.

9. The plating system of claim 6, wherein;
in the first position of the first sub-plate over the second sub-plate, the first and second portions of the first substrate specific pattern of openings are aligned;
wherein in the second position of the first sub-plate over the second sub-plate, the first and second portions of the first substrate specific pattern of openings are aligned; and
in a third position of the first sub-plate over the second sub-plate, the slot openings in the first sub-plate are aligned with the slot openings in the second sub-plate.

10. The plating system of claim 1, further comprising a moveable paddle interposed between the substrate support and the diffuser.

11. A diffuser for a plating system, comprising;
a first sub-plate and a second sub-plate, the first sub-plate positionable on the second sub-plate in at least a first position and a second position;
a portion of a first substrate specific pattern of openings extending through the first sub-plate and disposed in the first sub-plate at a plurality of first locations of the first plate and a portion of a second substrate specific pattern of openings extending through the second sub-plate and disposed in the first sub-plate at a plurality of second locations of the first sub-plate different than the first locations of the first sub-plate;
a portion of a first substrate specific pattern of openings extending through the second sub=plate disposed in the second sub-plate at a plurality of first locations of the first plate and a portion of a second substrate specific pattern of openings extending through the second sub-plate and disposed in the second sub-plate at a plurality of second locations of the second sub-plate different than the first locations of the second sub-plate; and
in the first position of the first sub-plate over the second sub-plate, the first and second portions of the first substrate specific pattern of openings are positioned to express the first substrate specific pattern of openings through the diffuser, and in the second position of the first sub-plate over the second sub-plate, the first and second portions of the second substrate specific pattern of openings through are positioned to express the second substrate specific pattern of openings through the diffuser.

12. The diffuser of claim 11, wherein the first and second portions of the first substrate specific pattern of openings are a series of elongated slot openings spaced from, and parallel to, one another extending through the first sub-plate and the second sub-plate.

13. The diffuser of claim 11, wherein the first and second portions of the second substrate specific pattern of openings are a plurality of openings extending through the first and second sub-plates in the regions of the first and second sub-plates between the first and second portions of the first substrate specific pattern of openings.

14. The diffuser of claim 12, wherein the second portion of the second substrate specific pattern of openings in the second sub-plate is disposed below a portion of the elongated slot openings when the first sub-plate is located over the first sub-plate in the second position.

15. The diffuser of claim 11, wherein the first and second portions of the first substrate specific pattern of openings are a plurality of openings extending in alternating strips through the first and second sub-plates, and the first and second portions of the second substrate specific pattern of openings are a plurality of openings extending in alternating strips, between the strips of openings of the first substrate specific pattern, through the first and second sub-plates.

16. The diffuser of claim 15, wherein the first and second portions of the first substrate specific pattern of openings are elongated slot openings extending through the first sub-plate between the adjacent stripes of the second substrate specific pattern of openings therein, and elongate slot openings extending through the second sub-plate between the adjacent stripes of the first and second substrate specific pattern therein.

17. The diffuser of claim 16, wherein in the first position of the first sub-plate over the second sub-plate, the first and second portions of the first substrate specific pattern of openings are aligned.

18. The diffuser of claim 17, wherein in the second position of the first sub-plate over the second sub-plate, the first portion of the first substrate specific pattern of openings is aligned with the second portion of the second substrate specific pattern of openings.

19. A method of plating at least two different plateable patterns on two different substrates, comprising:
providing a vessel;
providing a substrate support having a substrate support surface positionable in the vessel;
providing an anode in the vessel;
positioning a diffuser between the anode and the substrate support, the diffuser comprising a first sub-plate and a second sub-plate, the first sub-plate positionable in at least a first position and a second position relative to the second sub-plate in at least a first position and a second position, the diffuser including a first substrate specific pattern of openings expressible when the first sub-plate and second sub-plate are in the first position, and a second substrate specific pattern of openings when the first sub-plate and the second sub-plate are in the second position.

20. The method of claim 19, further comprising;
positioning a first substrate having a first plateable layer having a first plateable pattern thereon in the substrate support, and positioning the first plateable layer to face the diffuser;
positioning the first sub-plate relative to the second sub-plate in the first position, electroplating a material layer on the first plateable layer, and removing the first substrate from the substrate support;
positioning a second substrate having a second plateable layer having a second plateable pattern thereon different than the first plateable pattern of the first substrate, and positioning the second substrate on the substrate support, and positioning the second plateable layer to face the diffuser;
positioning the first sub-plate relative to the second sub-plate in the second position, electroplating a material layer on the second plateable layer, and removing the second substrate from the substrate support.
